(19) United States
(12) Patent Application Publication
(10) Pub. No.: US 2021/0189175 A1
(43) Pub. Date: Jun. 24, 2021

(54) POLISHING SYSTEMS AND METHOD OF MAKING AND USING SAME

(71) Applicant: 3M INNOVATIVE PROPERTIES COMPANY, St. Paul, MN (US)

(72) Inventors: John J. Gagliardi, Hudson, WI (US); Eric C. Coad, Woodbury, MN (US); Paul S. Lugg, Woodbury, MN (US)

(21) Appl. No.: 16/076,015

(22) PCT Filed: Feb. 10, 2017
(86) PCT No.: PCT/US2017/017379

§ 371 Date: Aug. 7, 2018

Related U.S. Application Data
(60) Provisional application No. 62/295,760, filed on Feb. 16, 2016.

(51) Int. Cl. C09G 1/02; B24B 37/04; C09K 3/14

(52) U.S. Cl. CPC C09G 1/02; C09K 3/1436; B24B 37/044

(57) ABSTRACT

A polishing system includes a substrate to be polished and a polishing pad. The polishing pad includes a base layer and a wear resistant layer. The system further includes a polishing solution disposed between the polishing pad and the substrate. The polishing solution includes a fluid component and a plurality of ceramic abrasive composites. The ceramic abrasive composites include individual abrasive particles uniformly dispersed throughout a porous ceramic matrix. At least a portion of the porous ceramic matrix includes glassy ceramic material. The ceramic abrasive composites are dispersed in the fluid component.

### FIELD

The present disclosure relates to polishing solutions useful for the polishing of substrates, and methods of using such polishing solutions.

### BACKGROUND

Various articles, systems, and methods have been introduced for the polishing of ultrahard substrates. Such articles, systems, and methods are described, for example, in C. Z. Li et. al., Proc. IMechE Vol. 225 Part B: J. Engineering Manufacture, and Y. Wang, et. al, Advanced Materials Research Vols. 126-128 (2010) pp 429-434 (2010) Trans Tech Publications, Switzerland.

### SUMMARY

In some embodiments, a polishing system is provided. The system includes a substrate to be polished and a polishing pad. The polishing pad includes a base layer and a wear resistant layer. The system further includes a polishing solution disposed between the polishing pad and the substrate. The polishing solution includes a fluid component; and a plurality of ceramic abrasive composites. The ceramic abrasive composites include individual abrasive particles uniformly dispersed throughout a porous ceramic matrix. At least a portion of the porous ceramic matrix includes glassy ceramic material. The ceramic abrasive composites are dispersed in the fluid component.

In some embodiments, a method of polishing a substrate is provided. The method includes providing a substrate to be polished and providing a polishing pad. The polishing pad includes a base layer and a wear resistant layer. The method further includes providing a polishing solution. The polishing solution includes a fluid component and a plurality of ceramic abrasive composites. The ceramic abrasive composites include individual abrasive particles uniformly dispersed throughout a porous ceramic matrix. At least a portion of the porous ceramic matrix comprises glassy ceramic material. The ceramic abrasive composites are dispersed in the fluid component. The method further includes positioning the polishing solution between the substrate and the polishing pad and moving the substrate and polishing pad relative to one another such that the substrate is polished.

The above summary of the present disclosure is not intended to describe each embodiment of the present disclosure. The details of one or more embodiments of the disclosure are also set forth in the description below. Other features, objects, and advantages of the disclosure will be apparent from the description and from the claims.

### BRIEF DESCRIPTION OF THE DRAWINGS

The disclosure may be more completely understood in consideration of the following detailed description of various embodiments of the disclosure in connection with the accompanying figures, in which:

FIG. 1 illustrates a schematic of an example of a polishing system for utilizing the articles and methods in accordance with some embodiments of the present disclosure.

FIG. 2A illustrates a perspective top view of a polishing pad in accordance with some embodiments of the present disclosure.

FIGS. 2B and 2C illustrate schematic cross-sectional views of polishing pads in accordance with some embodiments of the present disclosure.

### DETAILED DESCRIPTION

### Definitions

As used herein, the singular forms “a”, “an”, and “the” include plural referents unless the content clearly dictates otherwise. As used in this specification and the appended embodiments, the term “or” is generally employed in its sense including “and/or” unless the content clearly dictates otherwise.

As used herein, the recitation of numerical ranges by endpoints includes all numbers subsumed within that range (e.g. 1 to 5 includes 1, 1.5, 2, 2.75, 3, 3.8, 4, and 5).

Unless otherwise indicated, all numbers expressing quantities or ingredients, measurement of properties and so forth used in the specification and embodiments are to be understood as being modified in all instances by the term “about.” Accordingly, unless indicated to the contrary, the numerical parameters set forth in the foregoing specification and attached listing of embodiments can vary depending upon the desired properties sought to be obtained by those skilled in the art utilizing the teachings of the present disclosure. At the very least, and not as an attempt to limit the application of the doctrine of equivalents to the scope of the claimed embodiments, each numerical parameter should at least be construed in light of the number of reported significant digits and by applying ordinary rounding techniques.

Currently, ultrahard substrate (e.g., sapphire substrates) finishing processes are fixed abrasive processes or abrasive processes that involve the use of abrasive charged metal plates followed by chemical mechanical polishing with colloidal silica slurry. The challenges of lapping and polishing ultrahard substrates have not been satisfied using known versions of such processes. For example, inadequate material removal rates, poor surface finish, sub surface damage, high cost, and overall process difficulty have all been associated with such known processes.

The present disclosure is directed to articles, systems, and methods useful for polishing ultrahard substrates that overcomes many of the aforementioned problems associated with conventional abrasive processes.

Mechanical and chemical-mechanical planarization processes remove material from the surface of substrates (e.g., semiconductor wafers, field emission displays and many other microelectronic substrates) to form a flat surface at a desired elevation in the substrates.

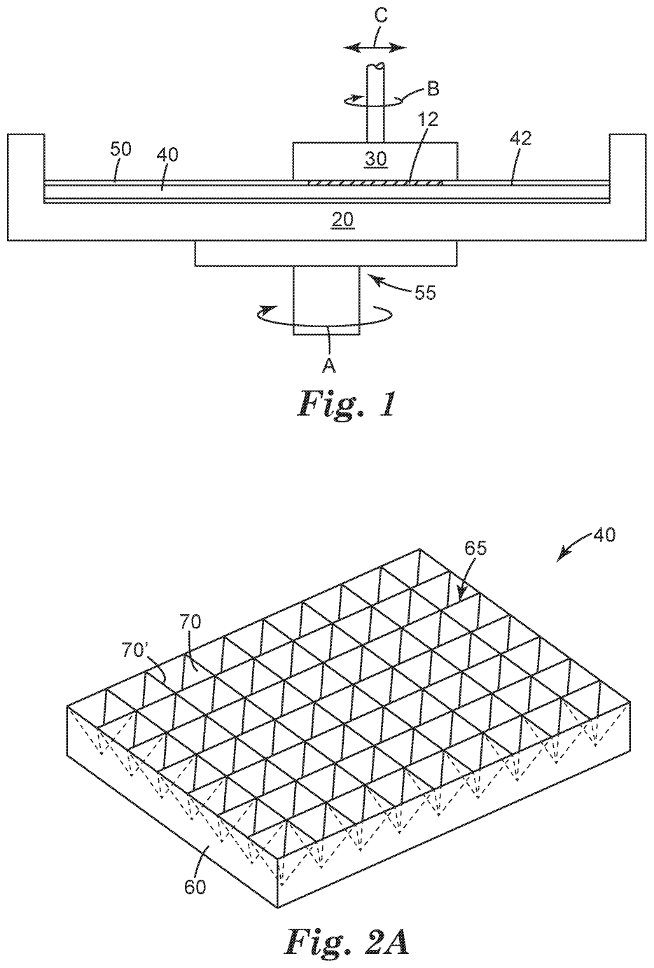

FIG. 1 schematically illustrates an example of a polishing system 10 for utilizing articles and methods in accordance with some embodiments of the present disclosure. As shown, the system 10 may include a platen 20, a carrier assembly 30, a polishing pad 40, and a layer of a polishing solution 50 disposed about a major surface of the polishing pad 40. During operation of the polishing system 10, a drive assembly 55 may rotate (arrow A) the platen 20 to move the polishing pad 40 to carry out a polishing operation. The polishing pad 40 and the polishing solution 50 may separately, or in combination, define a polishing environment that mechanically and/or chemically removes material from or polishes a major surface of a substrate 12. To polish the major surface of the substrate 12 with the polishing system 10, the carrier assembly 30 may press the substrate 12 against a polishing surface 42 of the polishing pad 40 in the presence of the polishing solution 50. The platen 20 (and thus the polishing pad 40) and/or the carrier assembly 30 then move relative to one another to translate the substrate 12 across the working surface 42 of the polishing pad 40. The carrier assembly 30 may rotate (arrow B) and optionally transverse laterally (arrow C). As a result, the abrasive particles (which may be contained in the polishing pad 40 and/or the polishing solution 50) and/or the chemicals in the polishing environment remove material from the surface of the substrate 12. It is to be appreciated that the polishing system 10 of FIG. 1 is only one example of a polishing system that may be employed in connection with the articles and methods of the present disclosure, and that other conventional polishing systems may be employed without deviating from the scope of the present disclosure.

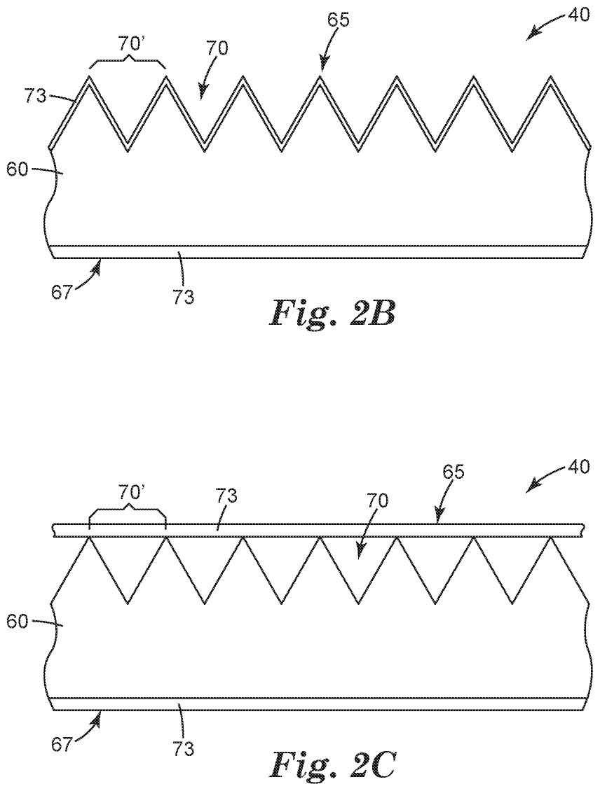

In some embodiments, the polishing pad 40 of the present disclosure may include a base layer of polymeric material having first and second major surfaces 65, 67 (e.g., first and second major planar surfaces). The polishing pad may further include a plurality of cavities that extend into the base layer from either or both of the first and second major surfaces 65, 67 of the base layer. For example, as shown in FIGS. 2A-2C, a polishing pad 40 may include a base layer 60 having a first major surface 65 and of plurality of cavities 70 that extend into the base layer 60 from the first major surface 65. The cavities 70 may extend into the base layer 60 any desired distance (including entirely through the base layer 60). Alternatively, either or both of the first and second major surfaces of the base layer 60 may be continuous surfaces (i.e., not include cavities). In embodiments in which a first major surface includes cavities and a second major surface is continuous, it is to be appreciated that either major surface may be employed as the working surface 42 (i.e., the surface of the pad that is nearest the substrate to be polished and that is intended to contact the polishing solution during the polishing process).

In illustrative embodiments, the base layer of the polishing pad 40 may be formed of a polymeric material. For example, the base layer may be formed from thermoplastics, for example; polypropylene, polyethylene, polycarbonate, polyurethane, polytetrafluoroethylene, polyethylene teraphthalate, polyethylene oxide, polysulphone, polyetherketone, polyetheretherketone, polyimides, polyphenylene sulfide, polystyrene, polyoxymethylene plastic, and the like; thermosets, for example polyurethanes, epoxy resin, phenoxy resins, phenolic resins, melamine resins, polyimides and urea-formaldehyde resins, radiation cured resins, or combinations thereof. In some embodiments, the base layer may include or be formed from polypropylene. The base layer may consist essentially of only one layer of material, or it may have a multilayered construction. For example, the base layer may include a plurality of layers, or layer stack, with the individual layers of the stack being coupled to one another with a suitable fastening mechanism (e.g, adhesive). The base layer (or an individual layer of the layer stack) may have any shape and thickness. The thickness of the base layer (i.e., the dimension of the base layer in a direction normal to the first and second major surfaces) may be less than 10 mm, less than 5 mm, less than 1 mm, less than 0.5 mm, less than 0.25 mm, less than 0.125 mm, or less than 0.05 mm.

In various embodiments, the cavities 70 may have any size and shape. For example, the shape of the cavities may be selected from among a number of geometric shapes such as a cubic, cylindrical, prismatic, hemispherical, rectangular, pyramidal, truncated pyramidal, conical, truncated conical, cross, post-like with a bottom surface which is arcuate or flat, or combinations thereof. Alternatively, some or all of the cavities may have an irregular shape. In some embodiments, each of the cavities has the same shape. Alternatively, any number of the cavities may have a shape that is different from any number of the other cavities.

In various embodiments, one or more of the side or inner walls that form the cavities may be perpendicular relative to the top major surface or, alternatively, may be tapered in either direction (i.e., tapered toward the bottom of the cavity or the toward top of the cavity (toward the major surface)). The angle forming the taper can range from about 1 to 75 degrees, from about 2 to 50 degrees, from about 3 to 35 degrees, or from between about 5 to 15 degrees. The height, or depth, of the cavities can be at least 1 μm, at least 10 μm, or at least 800 μm; less than 10 mm, less than 5 mm, or less than 1 mm. The height of the cavities 70 may be the same, or one or more of the cavities may have a height that is different than any number of other cavities 70.

In some embodiments, the cavities 70 may have a cavity opening 70′ defined in first the first major surface 65, the cavity openings 70′ having a length (the longest dimension of the cavity in the plane of the major surface) of at least 2 μm, at least 25 μm, at least 50 μm or at least 100 μm; less than 20 mm, less than 10 mm, less than 5 mm or less than 1 mm; and a width (the shortest dimension of the cavity in the plane of the major surface) of at least 2 μm, at least 25 μm, at least 50 μm or at least 100 μm; less than 20 mm, less than 10 mm, less than 5 mm or less than 1 mm. In various embodiments, one or more of the cavity openings 70′ (up to all of the cavities) is non-groove like (that is, the length to width ratio of the cavity opening 70′ is 1, less than 1.5, less than 2, or less than 3).

In illustrative embodiments, one or more (up to all) of the cavities may be formed as pyramids, or truncated pyramids. Such pyramidal shapes may have three to six sides (not including the base side), although a larger or smaller number of sides may be employed.

In some embodiments, the cavities 70 can be provided in an arrangement in which the cavities 70 are in aligned rows and columns. In some instances, one or more rows of cavities 70 can be directly aligned with an adjacent row of cavities 70. Alternatively, one or more rows of cavities 70 can be offset from an adjacent row of cavities 70. In further embodiments, the cavities 70 can be arranged in a spiral, helix, corkscrew, or lattice fashion. In still further embodiments, the cavities 70 can be arranged in a “random” array (i.e., not in an organized pattern).

In various embodiments, the cavity openings 70′ of the cavities 70 can abut (or nearly abut) one another or, alternatively, the cavity openings 70′ may be separated from one another by some specified distance. The spacing of the cavity openings 70′ can be at least 5,000 openings per linear cm, at least 400 openings per linear cm, at least 200 openings per linear cm or at least 100 openings per linear cm; less than 0.5 opening per linear cm, less than 1 opening per linear cm, less than 2 openings per linear cm or less than 10 openings per linear cm. In addition, the spacing can be varied such that the concentration of the cavity openings 70′ is greater in one location than in another (e.g., the concentration may be greatest in the center of the major surface). In some embodiments, there is an area spacing density of at least 1 openings/4 cm², at least 1 openings/cm², at least 4 openings/cm², at least 100 openings/cm² or at least 1,000 openings/cm². The area spacing density of composites ranges from about 1 opening/4 cm² to 40,000 openings/cm², about 20 to 10,000 openings/cm², or about 50 to 5,000 openings/cm².

In some embodiments, in conjunction with any of the previously described embodiments, one or more (up to all) of the cavities 70 among the array of cavities may be at least partially filled with a material to facilitate performance improvements of the polishing pad 30. Suitable cavity filling materials may include ductile metals, waxes, polishing pitch, porous materials of organic or inorganic composition, or combinations thereof. The cavity filling material may fill any portion (up to all) of the volume of a cavity. Each of the cavities may be provided with the same cavity filling material and/or filling levels, or may be provided with different filling materials and/or filling levels. By creating a cavity having a low bearing area, the effective pressure can be increased thus increasing the removal rates, as associated with the Preston equation, and the like. Filling the cavity with a resilient or ductile material such as polishing pitch or foam may have little impact on the bearing area since the particles will reflect away from the workpiece, however the “filling” may effectively supply the abrasive working particles to the point of working bearing area. If the cavity is too deep, particles may deposit in the base of the cavity and potentially be removed from the active polishing region or bearing area. Foam material such as porous polyurethane is another example of cavity filler used to create a delivery of abrasive particles to the high pressure region. Loosely bound particle additives such as plated white alumina may also be added to the cavities as a grinding aid, to enhance the removal rate or surface finish of the workpiece being polished.

In some embodiments, a wear resistant coating may overlay a portion (up to all) of either or both of the first and second major surfaces of the polishing pad. For example, as shown in FIG. 2B, a wear resistant coating 73 may overlay and conform or substantially conform to the major surfaces 65, 67 (including the inner surfaces of the cavities 70). Alternatively, as shown in FIG. 2C, the wear resistant coating 73 may not conform or substantially conform to the major surfaces 65, 67, but be disposed as a planar or substantially planar coating. Surprisingly, it has been discovered that polishing pads bearing certain wear resistant coatings may provide removal rates that approximate those achieved by uncoated polishing pads, while substantially increasing the working life of the polishing pad. While FIGS. 2B and 2C depict a wear resistant coating 73 overlaying both the first and second major surfaces 65, 67, it is to be appreciated that the wear resistant coating 73 may be present on only the working surface of the polishing pad.

In some embodiments, the wear resistant coating 73 may include or be formed of a polymeric material. The polymeric material may be selected such that it is conformable or substantially conformable to the shape of the structure it overlies. For example, the wear resistant coating 73 may include or be formed of ultra high molecular weight polyethylene, polyphenylene sulfide, ABS, Tefzel [ETFE], polycarbonate, Hytrel [TPE], or the like. In some embodiments, the wear resist coating 73 may be present at an average thickness of between 0.1 and 20, 1 and 10, 1 and 5, or 2 and 5 mils. The thickness of the wear resistant coating 73 may be uniform across the surface it overlies (e.g, the thickness at any one point may vary less than 10% or less than 20% than any other point across the surface). The wear resistant coating may be deposited onto the polishing pad by any conventional mechanism such as, for example, using a pressure sensitive adhesive, co-extrusion, or other adhesives.

In some embodiments, the polishing pads of the present disclosure may include one or more additional layers. For example, the polishing pad may include adhesive layers such as pressure sensitive adhesives, hot melt adhesives, or epoxies. “Sub pads” such as thermoplastic layers, e.g. polycarbonate layers, which may impart greater stiffness to the pad, may be used for global planarity. Sub pads may also include compressible material layers, e.g. foamed material layers. Sub pads which include combinations of both thermoplastic and compressible material layers may also be used. Additionally, or alternatively, metallic films for static elimination or sensor signal monitoring, optically clear layers for light transmission, foam layers for finer finish of the workpiece, or ribbed materials for imparting a “hard band” or stiff region to the polishing surface may be included.

As will be appreciated by those skilled in the art, the polishing pads of the present disclosure can be formed according to a variety of methods including, e.g., molding, extruding, embossing and combinations thereof.

In some embodiments, the polishing solution 50 (commonly referred to as a “slurry”) of the present disclosure may include a fluid component having abrasive composites dispersed and/or suspended therein.

In various embodiments, the fluid component may be non-aqueous or aqueous. A non-aqueous fluid is defined as having at least 50% by weight of a non-aqueous fluid, e.g., an organic solvent. An aqueous fluid is defined as having at least 50% by weight water. Non aqueous fluid components may include alcohols; e.g. ethanol, propanol, isopropanol, butanol, ethylene glycol, propylene glycol, glycerol, polyethylene glycol, triethylene glycol; acetates, e.g. ethyl acetate, triacetin, butyl acetate; ketones, e.g. methyl ethyl ketone, organic acids, e.g., acetic acid; ethers; triethanolamine; complexes of triethanolamine such as silitrane or boron equivalents, or combinations thereof. Aqueous fluid components may include (in addition to water) non-aqueous fluid components, including any of the non-aqueous fluids described above. The fluid component may consist essentially of water, or the amount of water in the fluid component may be at least 50% by weight, at least 70% by weight, at least 90% by weight or at least 95% by weight. The fluid component may consist essentially of a non-aqueous fluid, or the amount of non-aqueous fluid in the fluid component may be at least 50% by weight, at least 70% by weight, at least 90% by weight or at least 95% by weight. When the fluid component includes both aqueous and non-aqueous fluids, the resulting fluid component may be homogeneous, i.e. a single phase solution.

In illustrative embodiments, the fluid component may be selected such that the abrasive composite particles are insoluble in the fluid component.

In some embodiments, the fluid component may further include one or more additives such as, for example, dispersion aids, rheology modifiers, corrosion inhibitors, pH modifiers, surfactants, chelating agents/complexing agents, passivating agents, foam inhibitor, and combinations thereof. Dispersion aids are often added to prevent the sagging, settling, precipitation, and/or flocculation of the agglomerate particles within the slurry, which may lead to inconsistent or unfavorable polishing performance. Useful dispersants may include amine dispersants, which are reaction products of relatively high molecular weight aliphatic or alicyclic halides and amines, such as polyalkylene polyamines and Mannich dispersants, which are the reaction products of alkyl phenols in which the alkyl group contains at least 30 carbon atoms with aldehydes (especially formaldehyde) and amines (especially polyalkylene polyamines). Examples of amine dispersants are described in U.S. Pat. Nos. 3,275,554; 3,438,757; 3,454,555, and 3,565,804, all incorporated herein by reference. Examples of Mannich dispersants are described in U.S. Pat. Nos. 3,036,003; 3,236,770; 3,414,347; 3,448,047; 3,461,172; 3,539,633; 3,586,629; 3,591,598; 3,634,515; 3,725,480; 3,726,882, and 3,980,569, incorporated herein by reference.

Dispersive aids which provide steric stabilization may be used, such as those available under the trade designation SOLSPERSE, CARBOSPERSE and IRCOSPERSE, from Lubrizol Corporation, Wickliffe, Ohio. Additional dispersants include DISPERBYK additives such as DISPERBYK 180 from BYK Additives and Instruments, Wesel, Germany and DISPERS additives, including TEGO DISPERS 652, TEGO DISPERS 656 and TEGO DISPERSE 670, from Evonik Industries Hopewell, Va. Dispersion aids may be used alone or in combination of two or more.

Rheology modifiers may include shear thinning and shear thicknening agents. Shear-thinning agents may include polyamide waxes coated on polyolefin polymer material available under the trade designation DISPARLON from King Industries, Inc, Norwalk, Conn., including DISPARLON AQH-800, DISPARLON 6100, DISPARLON BB-102. Certain clays, such as Montmorillonite clay, may also be added as a shear thinning agent. Rheology modifiers may be used alone or in combination of two or more.

Thickening agents may include fumed silica, such as those available under the trade designation CAB-O-SIL from Cabot Corporation, Boston, Mass. and AEROSIL from Evonik Industires; SOLTHIX RHEOLOGY MODIFIERS and IRCOGEL from Lubrizol Corporation; water-soluble polymers, e.g. polyvinylpyrrolidone, polyethyleneimine, cellulose derivatives (hydroxypropylmethyl cellulose, hydroxyethyl cellulose, cellulose acetate butyrate, etc.) polyvinyl alcohol, poly(meth)acrylic acid, polyethylene glycol, poly(meth)acrylamide, polystyrene sulfonate, or any combinations thereof; non-aqueous polymers, e.g. polyolefins, styrene/maleic ester copolymers, and similar polymeric substances including homopolymers, copolymers and graft copolymers. The agents may comprise a nitrogen-containing methacrylate polymer, for example, a nitrogen-containing methacrylate polymer derived from methyl methacrylate and dimethylaminopropyl amine. Examples of commercially available materials include polyisobutylenes, such as INDOPAL from BP, London, England and or PARAPOL from ExxonMobil, Irving, Tex.; olefin copolymers, such as LUBRIZOL 7060, 7065, and 7067 from Lubrizol Corporation and LUCANT HC-2000L and LUCANT HC-600 from Mitsui Chemicals, Tokyo, Japan; hydrogenated styrene-diene copolymers, such as SHELLVIS 40 and SHELLVIS 50 from Shell Chemicals, Houston, Tex. and LZ 7308 and LZ 7318 from Lubrizol Corporation; styrene/maleate copolymers, such as LZ 3702 and LZ 3715 from Lubrizol Corporaton; polymethacrylates, such as those available under the trade designation VISCOPLEX from Evonik RohMax USA, Inc., Horsham, Pa., HITEC series of viscosity index improvers from Afton Chemical Corporation, Richmond, Va., and LZ 7702, LZ 7727, LZ7725 and LZ 7720C from Lubrizol Corporation; olefin-graft-polymethacrylate polymers such as VISCOPLEX 2-500 and VISCOPLEX 2-600 from Evonik RohMax USA, Inc.; and hydrogenated polyisoprene star polymers, such as SHELLVIS 200 and SHELLVIS 260, from Shell Chemicals. Other materials include methacrylate polymers with radial or star architecture, such as ASTERIC polymers from Lubrizol Corporation. Viscosity modifiers that may be used are described in U.S. Pat. Nos. 5,157,088; 5,256,752 and 5,395,539, incorporated herein by reference. Viscosity modifiers may be used alone or in combination of two or more.

Corrosion inhibitors that may be added to the fluid component include alkaline materials, which can neutralize the acidic byproducts of the polishing process that can degrade metal such as triethanolamine, fatty amines, octylamine octanoate, and condensation products of dodecenyl succinic acid or anhydride and a fatty acid such as oleic acid with a polyamine. Corrosions inhibitors may be used alone or in combination of two or more.

Suitable pH modifiers which may be used include alkali metal hydroxides, alkaline earth metal hydroxides, basic salts, organic amines, ammonia, and ammonium salts. Examples include potassium hydroxide, sodium hydroxide, calcium hydroxide, ammonium hydroxide, sodium borate, ammonium chloride, triethylamine, triethanolamine, diethanolamine, and ethylenediamine. Some pH modifiers, such as diethanolamine and triethanolamine, may also be capable of forming chelate complexes with metal impurities such as aluminum ions during metal polishing. Buffer systems may also be employed. The buffers can be adjusted to span the pH range from acidic to near-neutral to basic. Polyprotic acids act as buffers, and when fully or partially neutralized with ammonium hydroxide to make ammonium salts, they are representative examples including systems of phosphoric acid-ammonium phosphate; polyphosphoric acid-ammonium polyphosphate; the boric acid-ammonium tetraborate; boric acid-ammonium pentaborate pH modifiers may be used alone or in combination of two or more. Other buffers include tri- and polyprotic protolytes and their salts (e.g., ammonium salts). These may include ammonium ion buffer systems based on the following protolytes, all of which have at least one pKa greater than 7: aspartic acid, glutamic acid, histidine, lysine, arginine, ornithine, cysteine, tyrosine, and carnosine.

Surfactants that may be used include ionic and nonionic surfactants. Nonionic surfactants may include polymers containing hydrophilic and hydrophobic segments, such as poly(propylene glycol)-block-poly(ethylene glycol)-block-poly(propylene glycol) available under the trade designation PLURONIC from BASF Corporation, Florham Park, N.J.; poly(ethylene)-block-poly(ethylene glycol) available under the trade designation BRIJ from Croda International PLC, Edison, N.J.; nonylphenol ethoxylate available under the trade designation TERGITOL from Dow Chemical, Midland, Mich. and polyethylene glycol sorbitan monostearate available under the trade designation TWEEN 60 and other TWEEN surfactants from Croda International PLC.

Ionic surfactants may include both cationic surfactants and anionic surfactants. Cationic surfactants include quaternary ammonium salts, sulfonates, carboxylates, linear alkyl-amines. alkylbenzene sulfonates (detergents), (fatty acid) soaps, lauryl sulfates, di-alkyl sulfosuccinate and lignosulfonates. Anionic Surfactants are dissociated in water in an amphiphilic anion, and a cation, which is in general an alkaline metal (Na+, K+) or a quaternary ammonium. Types include Laureth-carboxylic acid such as AKYPO RLM-25 from KAO Chemicals, Kao Specialties Americas LLC, High Point, N.C. Surfactants may be used alone or in combination of two or more.

Complexing agents, such as ligands and chelating agents, may be included in the fluid component, particularly when the application relates to metal finishing or polishing, where metal swarf and or metal ions may be present in the fluid component during use. The oxidation and dissolution of metal can be enhanced by the addition of complexing agents. These compounds can bond to metal to increase the solubility of metal or metal oxides in aqueous and non-aqueous liquids, as generally described in Cotton & Wilkinson; and Hathaway in Comprehensive Coordination Chemistry, Vol. 5; Wilkinson, Gillard, McCleverty, Eds. Suitable additives that may be added to or used in the liquid component include monodentate complexing agents, such as ammonia, amines, halides, pseudohalides, carboxylates, thiolates, and the like also called ligands. Other additives that may be added to the working liquid include multidentate complexing agents, typically multidentate amines. Suitable multidentate amines include ethylenediamine, diethylene-triamine, triethylenetetramine, or combinations thereof. Combinations of the two monodentate and polydentate complexing agents include amino acids such as glycine, and common analytical chelating agents such as EDTA-ethylenediaminetetraacetic acid and its numerous analogs. Additional chelators include: polyphosphates, 1,3-diketones, aminoalcohols, aromatic heterocyclic bases, phenols, aminophenols, oximes, Schiff bases, and sulfur compounds. Examples of suitable complexing agents (particularly in the case when metal oxide surfaces are being polished) include ammonium salts such as NH₄HCO₃, tannic acid, catechol, Ce(OH)(NO)₃; Ce(SO₄)₂, phthalic acid, salicyclic acid and the like.

Complexing agents may include carboxylic acids and salts thereof that having one carboxyl group (i.e., monofunctional carboxylic acids) or a plurality of carboxylic acid groups (i.e., multifunctional carboxylic acids), e.g., difunctional carboxylic acids (i.e., dicarboxylic acids) and trifunctional carboxylic acids (i.e., tricarboxylic acids). As used herein, the terms “monofunctional”, “difunctional”, “trifunctional,” and “multifunctional” refer to the number of carboxyl groups on the acid molecule. Complexing agents may include simple carboxylic acids, which consist of carbon, hydrogen, and one or more carboxyl groups. Exemplary monofunctional simple carboxylic acids include, e.g., formic, acetic, propionic, butyric, isobutyric acid, 3-butenoic acid, capric, lauric, stearic, oleic, linoleic, linolenic, phenylacetic, benzoic, and toluic acids. Exemplary multifunctional simple carboxylic acids include, e.g., oxalic, malonic, methylmalonic, succinic, glutaric, adipic, maleic, fumaric, phthalic, isophthalic, and terephthalic acids. Complexing agents may include substituted carboxylic acids contain one or more substituents, e.g., halides, hydroxyl groups, amino groups, ether groups, and/or carbonyl groups in addition to the one or more carboxyl groups. Hydroxy-carboxylic acids, which comprise one or more hydroxyl groups, are one class of substituted carboxylic acid. Exemplary hydroxy-carboxylic acids include monofunctional hydroxy-carboxylic acids and multifunctional hydroxy-carboxylic acids. Exemplary monofunctional hydroxy-carboxylic acids include glyceric acid (i.e., 2,3-dihydroxypropanoic acid), glycolic acid, lactic acid (e.g., L-lactic, D-lactic, and DL-lactic acids), hydroxy-butanoic acid, 3-hydroxypropionic acid, gluconic acid and methyllactic acid (i.e., 2-hydroxyisobutyric acid). Exemplary multifunctional hydroxy-carboxylic acids include malic acid and tartaric acid (difunctional hydroxy-carboxylic acids) and citric acid (a trifunctional hydroxy-carboxylic acid). Complexing agents may be used alone or in combination of two or more.

Passivating agents may be added to the fluid component to create a passivating layer on the substrate being polished, thereby altering the removal rate of a given substrate or adjusting the removal rate of one material relative to another material, when the substrate contains a surface that includes two or more different materials. Passivating agents known in the art for passivating metal substrates may be used, including benzotriazole and corresponding analogs. Passivating agents known to passivate inorganic oxide substrates, include amino acids, e.g. glycine, aspartic acid, glutamic acid, histidine, lysine, proline, arginine, cysteine, and tyronsine may be used. Additionally, ionic and non-ionic surfactants may also function as passivating agents. Passivating agents may be used alone or in combination of two or more, e.g. an amino acid and a surfactant.

Foam inhibitors that may be used include silicones; copolymers of ethyl acrylate and 2-ethylhexylacrylate, which can optionally further include vinyl acetate; and demulsifiers including trialkyl phosphates, polyethylene glycols, polyethylene oxides, polypropylene oxides and (ethylene oxide-propylene oxide) polymers. Foam inhibitors may be used alone or in combination of two or more. Other additives that may be useful in the fluid component include oxidizing and/or bleaching agents such as, e.g. hydrogen peroxide, nitric acid, and transition metal complexes such as ferric nitrate; lubricants; biocides; soaps and the like.

In various embodiments, the concentration of an additive class, i.e. the concentration of one or more additives from a single additive class, in the polishing solution may be at least about 0.01 wt. %, at least about, 0.1 wt. %, at least about 0.25 wt. %, at least about 0.5 or at least about 1.0 wt. %; less than about 20 wt. %, less than about 10 wt. %, less than about 5 wt. % or less than about 3 wt % based on the weight of the polishing solution.

In illustrative embodiments, the abrasive composites of the present disclosure may include porous ceramic abrasive composites. The porous ceramic abrasive composites may include individual abrasive particles dispersed in a porous ceramic matrix. As used herein the term “ceramic matrix” includes both glassy and crystalline ceramic materials. These materials generally fall within the same category when considering atomic structure. The bonding of the adjacent atoms is the result of process of electron transfer or electron sharing. Alternatively, weaker bonds as a result of attraction of positive and negative charge known as secondary bond can exist. Crystalline ceramics, glass and glass ceramics have ionic and covalent bonding. Ionic bonding is achieved as a result of electron transfer from one atom to another. Covalent bonding is the result of sharing valence electrons and is highly directional. By way of comparison, the primary bond in metals is known as a metallic bond and involves non-directional sharing of electrons. Crystalline ceramics can be subdivided into silica based silicates (such as fireclay, mullite, porcelain, and Portland cement), non-silicate oxides (e.g., alumna, magnesia, MgAl₂O₄, and zirconia) and non-oxide ceramics (e.g., carbides, nitrides and graphite). Glass ceramics are comparable in composition with crystalline ceramics. As a result of specific processing techniques, these materials do not have the long range order crystalline ceramics do. Glass ceramics are the result of controlled heat-treatment to produce at least about 30% crystalline phase and up to about 90% crystalline phase or phases In illustrative embodiments, at least a portion of the ceramic matrix includes glassy ceramic material. In further embodiments, the ceramic matrix includes at least 50% by weight, 70% by weight, 75% by weight, 80% by weight, or 90% by weight glassy ceramic material. In one embodiment, the ceramic matrix consists essentially of glassy ceramic material.

In various embodiments, the ceramic matrixes may include glasses that include metal oxides, for example, aluminum oxide, boron oxide, silicon oxide, magnesium oxide, sodium oxide, manganese oxide, zinc oxide, and mixtures thereof. A ceramic matrix may include alumina-borosilicate glass including Si₂O, 8203, and Al₂O₃. The alumina-borosilicate glass may include about 18% B203, 8.5% Al₂O₃, 2.8% BaO, 1.1% CaO, 2.1% Na₂O, 1.0% Li₂O with the balance being Si₂O. Such an alumina-borosilicate glass is commercially available from Specialty Glass Incorporated, Oldsmar Fla.

As used herein the term “porous” is used to describe the structure of the ceramic matrix which is characterized by having pores or voids distributed throughout its mass. The pores may be open to the external surface of the composite or sealed. Pores in the ceramic matrix are believed to aid in the controlled breakdown of the ceramic abrasive composites leading to a release of used (i.e., dull) abrasive particles from the composites. The pores may also increase the performance (e.g., cut rate and surface finish) of the abrasive article, by providing a path for the removal of swarf and used abrasive particles from the interface between the abrasive article and the workpiece. The voids may comprise from about at least 4 volume % of the composite, at least 7 volume % of the composite, at least 10 volume % of the composite, or at least 20 volume % of the composite; less than 95 volume % of the composite, less than 90 volume % of the composite, less than 80 volume % of the composite, or less than 70 volume % of the composite. A porous ceramic matrix may be formed by techniques well known in the art, for example, by controlled firing of a ceramic matrix precursor or by the inclusion of pore forming agents, for example, glass bubbles, in the ceramic matrix precursor.

In some embodiments, the abrasive particles may include diamond, cubic boron nitride, fused aluminum oxide, ceramic aluminum oxide, heated treated aluminum oxide, silicon carbide, boron carbide, alumina zirconia, iron oxide, ceria, garnet, and combinations thereof. In one embodiment, the abrasive particles may include or consist essentially of diamond. Diamond abrasive particles may be natural or synthetically made diamond. The diamond particles may have a blocky shape with distinct facets associated with them or, alternatively, an irregular shape. The diamond particles may be mono-crystalline or polycrystalline such as diamond commercially available under the trade designation “Mypolex” from Mypodiamond Inc., Smithfield Pa. Monocrystalline diamond of various particles size may be obtained from Diamond Innovations, Worthington, Ohio. Polycrystalline diamond may be obtained from Tomei Corporation of America, Cedar Park, Tex. The diamond particles may contain a surface coating such as a metal coating (nickel, aluminum, copper or the like), an inorganic coating (for example, silica), or an organic coating.

In some embodiments, the abrasive particles may include a blend of abrasive particles. For example, diamond abrasive particles may be mixed with a second, softer type of abrasive particles. In such instance, the second abrasive particles may have a smaller average particle size than the diamond abrasive particles.

In illustrative embodiments, the abrasive particles may be uniformly (or substantially uniformly) distributed throughout the ceramic matrix. As used herein, “uniformly distributed” means that the unit average density of abrasive particles in a first portion of the composite particle does not vary by more than 20%, more than 15%, more than 10%, or more than 5% when compared with any second, different portion of the composite particle. This is in contrast to, for example, an abrasive composite particle having abrasive particles concentrated at the surface of the particle.

In various embodiments, the abrasive composite particles of the present disclosure may also include optional additives such as fillers, coupling agents, surfactants, foam suppressors and the like. The amounts of these materials may be selected to provide desired properties. Additionally, the abrasive composite particles may include (or have adhered to an outer surface thereof) one or more parting agents. As will be discussed in further detail below, one or more parting agents may used in the manufacture of the abrasive composite particles to prevent aggregation of the particles. Useful parting agents may include, for example, metal oxides (e.g, aluminum oxide), metal nitrides (e.g., silicon nitride), graphite, and combinations thereof.

In some embodiments, the abrasive composites useful in the articles and methods of the present disclosure may have an average size (average major axial diameter or longest straight line between two points on a composite) of about at least 5 μm, at least 10 μm, at least 15 μm, or at least 20 μm; less than 1,000 μm, less than 500 μm, less than 200 μm, or less than 100 μm.

In illustrative embodiments, the average size of the abrasive composites is at least about 3 times the average size of the abrasive particles used in the composites, at least about 5 times the average size of the abrasive particles used in the composites, or at least about 10 times the average size of the abrasive particles used in the composites; less than 30 times the average size of the abrasive particles used in the composites, less than 20 times the average size of the abrasive particles used in the composites, or less than 10 times the average size of the abrasive particles used in the composites. Abrasive particles useful in the articles and methods of the present disclosure may have an average particle size (average major axial diameter (or longest straight line between two points on a particle)) of at least about 0.5 μm, at least about 1 μm, or at least about 3 μm; less than about 300 μm, less than about 100 μm, or less than about 50 μm. The abrasive particle size may be selected to, for example, provide a desired cut rate and/or desired surface roughness on a workpiece. The abrasive particles may have a Mohs hardness of at least 8, at least 9, or at least 10.

In various embodiments, the weight of abrasive particles to the weight of glassy ceramic material in the ceramic matrix of the ceramic abrasive composites is at least about 1/20, at least about 1/10, at least about 1/6, at least about 1/3, less than about 30/1, less than about 20/1, less than about 15/1 or less than about 10/1.

In various embodiments, the amount of porous ceramic matrix in the ceramic abrasive composites is at least 5, at least 10, at least 15, at least 33, less than 95, less than 90, less than 80, or less than 70 weight percent of the total weight of the porous ceramic matrix and the individual abrasive particles, where the ceramic matrix includes any fillers, adhered parting agent and/or other additives other than the abrasive particles

In various embodiments, the abrasive composite particles may be precisely-shaped or irregularly shaped (i.e., non-precisely-shaped). Precisely-shaped ceramic abrasive composites may be any shape (e.g., cubic, block-like, cylindrical, prismatic, pyramidal, truncated pyramidal, conical, truncated conical, spherical, hemispherical, cross, or post-like). The abrasive composite particles may be a mixture of different abrasive composite shapes and/or sizes. Alternatively, the abrasive composite particles may have the same (or substantially the same) shape and/or size. Non-precisely shaped particles include spheroids, which may be formed from, for example, a spray drying process.

In various embodiments, the concentration of the abrasive composites in the fluid component may be at least 0.065 wt. %, at least 0.16 wt. %, at least 0.33 or at least 0.65 wt. %; less than 6.5 wt. %, less than 4.6 wt. %, less than 3.0 wt. % or less than 2.0 wt %. In some embodiments, both the ceramic abrasive composites and the parting agent used in their fabrication can be included in the fluid component. In these embodiments the concentration of the abrasive composites and the parting agent in the fluid component may be at least 0.1 wt. %, at least 0.25 wt. %, at least 0.5 or at least 1.0 wt. %; less than 10 wt. %, less than 7 wt. %, less than 5 wt. % or less than 3 wt.

The abrasive composite particles of the present disclosure may be formed by any particle forming processes including, for example, casting, replication, microreplication, molding, spraying, spray-drying, atomizing, coating, plating, depositing, heating, curing, cooling, solidification, compressing, compacting, extrusion, sintering, braising, atomization, infiltration, impregnation, vacuumization, blasting, breaking (depending on the choice of the matrix material) or any other available method. The composites may be formed as a larger article and then broken into smaller pieces, as for example, by crushing or by breaking along score lines within the larger article. If the composites are formed initially as a larger body, it may be desirable to select for use fragments within a narrower size range by one of the methods known to those familiar with the art. In some embodiments, the ceramic abrasive composites may include vitreous bonded diamond agglomerates produced generally using the method of U.S. Pat. Nos. 6,551,366 and 6,319,108, which is herein incorporated by reference in its entirety.

Generally, a method for making the ceramic abrasive composite may include mixing an organic binder, solvent, abrasive particles, e.g. diamond, and ceramic matrix precursor particles, e.g. glass frit; spray drying the mixture at elevated temperatures producing “green” abrasive/ceramic matrix/binder particles; the “green” abrasive/ceramic matrix/binder particles are collected and mixed with a parting agent, e.g. plated white alumina; the powder mixture is then annealed at a temperature sufficient to vitrify the ceramic matrix material that contains the abrasive particles while removing the binder through combustion; forming the ceramic abrasive composite. The ceramic abrasive composites can optionally be sieved to the desired particle size. The parting agent prevents the “green” abrasive/ceramic matrix/binder particles from aggregating together during the vitrifying process. This enables the vitrified, ceramic abrasive composites to maintain a similar size as that of the “green” abrasive/ceramic matrix/binder particles formed directly out of the spray drier. A small weight fraction, less than 10%, less 5% or even less than 1% of the parting agent may adhere to the outer surface of the ceramic matrix during the vitrifying process. The parting agent typically has a softening point (for glass materials and the like), or melting point (for crystalline materials and the like), or decomposition temperature, greater than the softening point of the ceramic matrix, wherein it is understood that not all materials have each of a melting point, a softening point, or a decomposition temperature. For a material that does have two or more of a melting point, a softening point, or a decomposition temperature, it is understood that the lower of the melting point, softening point, or decomposition temperature is greater than the softening point of the ceramic matrix. Examples of useful parting agents include, but are not limited to, metal oxides (e.g. aluminum oxide), metal nitrides (e.g. silicon nitride) and graphite.

In some embodiments, the abrasive composite particles of the present disclosure may be surface modified (e.g., covalently, ionically, or mechanically) with reagents which will impart properties beneficial to abrasive slurries. For example, surfaces of glass can be etched with acids or bases to create appropriate surface pH. Covalently modified surfaces can be created by reacting the particles with a surface treatment comprising one or more surface treatment agents. Examples of suitable surface treatment agents include silanes, titanates, zirconates, organophosphates, and organosulfonates. Examples of silane surface treatment agents suitable for this invention include octyltriethoxysilane, vinyl silanes (e.g., vinyltrimethoxysilane and vinyl triethoxysilane), tetramethyl chloro silane, rnethyltrimethoxysilane, methyltriethoxysilane, propyltrinethoxysilane, propyltriethoxysilane, tris-[3-(trimethoxysilyl)propyl] isocyanurate, vinyl-tris-(2-methoxyethoxy)silane, gamm-methacryloxypropyltrimethoxysilane, beta-(3,4-epoxycyclohexyl)ethyltrimethoxysilane, gamma-glycidoxypropyltrimethoxysilane gamma-mercaptopropyltrimethoxysilane, gamma-aminopropyltriethoxysilane, gamma-aminopropyltrimethoxysilane, N-beta-(aminoethiyl)-gamma-aminopropyltrimethoxysilane, bis-(gamma-trimethoxysilylpropyl)amine, N-phenyl-gamma-aminopropyltrirnethoxysilane, gamma-ureidopropyltrialkoxysilane, gamma-ureidopropyltrimethoxysilane, acryloxyalkyl trimethoxysilane, rnethacryloxyalkyl trimethoxysilane, phenyl trichlorosilane, phenyltrimethoxysilane, phenyl triethoxysilane, SILQUEST A1230 proprietary non-ionic silane dispersing agent (available from Momentive, Columbus, Ohio) and mixtures thereof. Examples of commercially available surface treatment agents include SILQUEST A174 and SILQUEST A1230 (available from Momentive). The surface treatment agents may be used to adjust the hydrophobic or hydrophilic nature of the surface it is modifying. Vinyl silanes can be used to provide an even more sophisticated surface modification by reacting the vinyl group w/ another reagent. Reactive or inert metals can be combined with the glass diamond particles to chemically or physically change the surface. Sputtering, vacuum evaporation, chemical vapor deposition (CVD) or molten metal techniques can be used.

The present disclosure further relates to methods of polishing substrates. The methods may be carried out using a polishing system such as that described with respect to FIG. 1, or with any other conventional polishing system, e.g. single or double sided polishing and lapping. In some embodiments, a method of polishing substrate may include providing a substrate to be polished. The substrate may be any substrate for which polishing and/or planarization is desirable. For example, the substrate may be a metal, metal alloy, metal oxide, ceramic, or polymer (commonly in the form of a semiconductor wafer or optical lens). In some embodiments, the methods of the present disclosure may be particularly useful for polishing ultrahard substrates such as sapphire (A, R, or C planes), silicon, silicon carbide, quartz, or silicate glasses. The substrate may have one or more surfaces to be polished.

In various embodiments, the method may further include providing a polishing pad and a polishing solution. The polishing pad and polishing solution may be the same as or similar to any of the polishing pads and the polishing solutions described above.

In some embodiments, the method may further include contacting a surface of the substrate with the polishing pad and the polishing solution while there is relative motion between the polishing pad and the substrate. For example, referring again to the polishing system of FIG. 1, the carrier assembly 30 may apply pressure to the substrate 12 against a polishing surface of the polishing pad 40 in the presence of the polishing solution 50 as the platen 20 is moved (e.g., translated and/or rotated) relative to the carrier assembly 30. Additionally, the carrier assembly 30 may be moved (e.g., translated and/or rotated) relative to the platen 20. Continued pressure and relative motion between the substrate and the polishing surface may then result in polishing of the substrate.

In illustrative embodiments, the systems and methods of the present disclosure are particularly suited for the finishing of ultra hard substrates such as sapphire, A, R, or C planes. Finished sapphire crystals, sheets or wafers are useful, for example, in the light emitting diode industry and cover layer for mobile hand held devices. In such applications, the systems and methods provide persistent removal of material. Furthermore, it has been discovered that systems and methods of the present disclosure can provide a removal rate commensurate with that achieved with large abrasive particle sizes conventionally employed, while providing a surface finish comparable to that achieved with small particle sizes conventionally employed. Still further, the systems and methods of the present disclosure are capable of providing persistent removal rates without extensive dressing of the pad, such as required with fixed abrasive pads. Further yet, it has been discovered that polishing pads of the present disclosure, which bear certain wear resistant coatings, provide removal rates and surface finishes that approximate those achieved by similar uncoated polishing pads, while substantially increasing the working life of the polishing pad.

The operation of the present disclosure will be further described with regard to the following detailed examples. These examples are offered to further illustrate the various specific and preferred embodiments and techniques. It should be understood, however, that many variations and modifications may be made while remaining within the scope of the present disclosure.

### EXAMPLES

### Materials

Materials

| Abbreviation or Trade Name | Description |
|---|---|
| MCD3A | A 3 micron monocrystalline diamond, available from |
| | World Wide Super Abrasives, Boynton Beach, Florida. |
| GF* | A glass frit having a particle size of about 10.6 microns, |
| | available under the trade designation “SP 1086” from |
| | Specialty Glass, Inc., Oldsmar, Florida. |
| AlOx | A 3 micron plated white alumina, available under the trade |
| | designation “PWA 3” from Fujimi Inc., Kiyosu, Japan. |
| Standex230 | Dextrin, available under the trade designation “STANDEX |
| | 230” from A. E. Staley Manufacturing Company, Decatur, |
| | Illinois. |
| TEG | Triethylene glycol, 99%, available from Sigma-Aldrich |
| | Co. LLC. |
| Carbopol Aqua 30 | Lubrizol Advanced Materials Inc., New Milford, CT., |
| | 06766 |
| Glycerol | ACS Reagent Grade > 99.5%, Sigma Aldrich of |
| | Milwaukee WI, 53201 |
| Kathon CG/ICP II | Rohm and Hass, Philadelphia PA. |
| Sodium hydroxide | ACS Reagent Grade > 97.0%, Sigma Aldrich of |
| | Milwaukee WI, 53201 |
| Gen II Pad | 3M 41-9103-5040-8, Polypropylene Pad from 3M St. Paul, |
| | MN 55144. |
| 442KW | 3M, Adhesive from 3M St. Paul, MN 55144. |
| 300LSE | 3M, Adhesive from 3M St. Paul, MN 55144. |
| Primer 94 | 3M, Primer 94 from 3M St. Paul, MN 55144. |
| Polycarbonate Pad Base | 30 mil Polycarbonate Sheet from Sabic Polymershapes, |
| | Naperville, IL 60540. |
| Polycarbonate Sheet | 25 mil Polycarbonate Sheet from Mc Master Carr, |
| | Chicago, IL 60680. |
| Nylon 6/6 Sheet | 30 mil Nylon 6/6 from CS Hyde Company, Lake Villa, IL |
| | 60046. |
| Polyphenylene Sulfide Film | 5 mil Polyphenylene Sulfide Film from CS Hyde |
| | Company, Lake Villa, IL 60046. |
| ABS Film | 3 mil ABS Film from CS Hyde Company, Lake Villa, IL |
| | 60046. |
| Tefzel (ETFE) Film | 5 mil Tefzel (ETFE) Film from CS Hyde Company, Lake |
| | Villa, IL 60046. |
| Polycarbonate Film | 5 mil Polycarbonate Sheet from Mc Master Carr, Chicago, |
| | IL 60680. |
| Hytrel (TPE) Film | 3 mil Hytrel (TPE) Film from CS Hyde Company, Lake |
| | Villa, IL 60046. |
| Udel (Polysulfone) Film | 5 mil Udel (Polysulfone) Film from CS Hyde Company, |
| | Lake Villa, IL 60046. |
| PEEK Film | 3 mil PEEK Film from CS Hyde Company, Lake Villa, IL |
| | 60046. |
| Ultem (Polyetherimide) Film | 3 mil Ultem (Polyetherimide) Film from CS Hyde |
| | Company, Lake Villa, IL 60046. |
| UMHW-PE 1 Film | 3M 3.1C UMHW-PE with Adhesive from 3M St. Paul, |
| | MN 55144. |
| Kynar (PVDF) Film | 3 mil Kynar (PVDF) Film from CS Hyde Company, Lake |
| | Villa, IL 60046. |
| UMHW-PE 2 Film | 3M 3.1F UMHW-PE with Adhesive from 3M St. Paul, |
| | MN 55144. |
| FEP Film | 3 mil FEP Film from CS Hyde Company, Lake Villa, IL |
| | 60046. |
| PTFE Film | 3 mil PTFE Film from CS Hyde Company, Lake Villa, IL |
| | 60046. |
| UMHW-PE 3 Film | 3M 9325 UMHW-PE with Adhesive from 3M St. Paul, |
| | MN 55144. |
| Polyoxymethylene Film | 4 mil Polyoxymethylene Film from CS Hyde Company, |
| | Lake Villa, IL 60046. |
| Polyesterterephalate Film | 3 mil Polyesterterephalate Film from Teijin DuPont Films |
| | Japan Limited. |
| Polyimide Film | 1 mil Polyimide Film from Liyang Huajing Electronic |
| | Material Co., Ltd., Liyang, Jiangsu, 213300, China. |
| Polyurethane Film | 3M Paint Protection Film from 3M St. Paul, MN 55144. |
| TPX (Polymethylpentene) | 3 mil TPX (Polymethylpentene) Film from CS Hyde |
| Film | Company, Lake Villa, IL 60046. |
| Polypropylene Film | 2 mil Polypropylene Film with adhesive from Mc Master |
| | Carr, Chicago, IL 60680. |
| Surlyn Film | 2 mil Surlyn Film from DuPont USA, Wilmington, DE |
| | 19880. |
| Yittria Stabilized Zirconia | 1 mm average diameter, Inframat Advanced Materials, |
| grinding media YSZ | Manchester CT, 06042 |
| Polypropylene modified | 3M St. Paul, MN 55144 |
| stem web, 41-9104-3120-8 | |
| Primer 94 | 3M St. Paul, MN 55144 |

*Particle size is the mean measured by conventional laser light scattering.

### Test Methods and Preparation Procedures

### Removal Rate Test Method 1

Sapphire wafers were measured gravimetrically before and after polishing. The measured weight loss was used to determine the amount of material removed, based on a wafer density of 3.98 g/cm³. For single sided polishing, removal rate, reported in microns/minute, is the average thickness reduction of the three wafers over the specified polishing interval. For double sided polishing, removal rate, reported in microns/minute, is the average thickness reduction of the three wafers out of nine over the specified polishing interval.

### Surface Roughness Test Method 1:

Surface roughness measurements; including Ra, Rmax, and Rz; were made using a contact stylus profilometer, Model P-16+ available from KLA-Tencor Corporation, Milpitas, Calif. The scan rate was 100 microns/sec and the scan length was 2500 microns. For single sided polishing, ten profilometer scans were conducted on the polished side of one of the three wafers and the data was averaged. For double sided polishing, ten profilometer scans were conducted on the top side of one of the nine wafers and the data of the ten scans was averaged.

### Polishing Test Method-1

Polishing was conducted using a Peter Wolters AC 500, Lapmaster Wolters, Rendsburg, Germany, double sided lapping tool. A 18.31 inch (46.5 cm) outer diameter, 7 inch (17.8 cm) inner diameter pad was mounted to the 18.31 inch (46.5 cm) outer diameter, 7 inch (17.8 cm) inner diameter bottom platen, of the polisher using a double sided PSA. The top pad was similar except for 16×1 cm slurry holes that were aligned to the hole pattern of the top platen to allow for slurry to travel to the workpiece and bottom pad. The platens were rotated at 60 rpm both in a clockwise direction. Three epoxy glass carriers comprising three, round holes, each sized to hold a 5.1 cm diameter wafer, were set onto the bottom pad and aligned to the tool gears. The recess center points were located equal distance from each other and were offset relative to the center of the carrier, such that when the carriers rotated, the center point of each recess would rotate in a circle with 1 cm of a wafer edge overhanging the pad/platen edge. Three, A-plane sapphire wafers, 5.1 cm diameter×0.5 cm thick, were mounted in each of the 3 carrier recesses and polished. Three carriers per batch for a total of 9 wafers per batch were run for 30 minutes. The highest load was applied to the wafers to achieve polishing pressure of 4 psi. The initial stage was set at 20 daN for 20 sec. with a rotational speed of 60 rpm running clockwise. The ring gear was set at 8, also in a clockwise direction. The second stage was set at 52 daN for 30 minutes with a final stage at 20 daN for 20 seconds. Slurry flow was constant at 6 g/min.

Wafers were measured gravimetrically before and after polishing. The measured weight loss was used to determine the amount of material removed, based on a wafer density of 3.98 g/cm³. Removal rate, reported in microns/minute, is the average thickness reduction of the three wafers over the 30 minute polishing interval. Wafers were re-used for each 30 minute period.

### Polishing Test Method-2

Polishing was conducted using a Engis Model FL 15 polisher, available from Engis Corp. of 105 W. Hinz Rd., Wheeling, Ill. 60090. A 15 inch (38.1 cm) diameter pad was mounted to the 15 inch (38.1 cm) diameter platen of the polisher using a double sided PSA. The platen was rotated at 50 rpm. The head of the polisher was rotated at 40 rpm, without a sweeping motion. A carrier comprising three recesses, each sized to hold a 5.1 cm diameter wafer, was mounted to the head. The recess center points were located equal distance from each other and were offset relative to the center of the head, such that when the head rotated, the center point of each recess would rotate in a circle having a 13.5 cm circumference. Three, A-plane sapphire wafers, 5.1 cm diameter×0.5 cm thick, were mounted in the carrier recesses and polished. Polishing time was 30 minutes. The load was applied to the wafers using weights of 30.7 lbs (13.9 kg) to achieve polishing pressure of 4 psi. The slurry flow rate was 1 g/min and dripped onto the pad at a point about 4 cm from the pad center.

Wafers were measured gravimetrically before and after polishing. The measured weight loss was used to determine the amount of material removed, based on a wafer density of 3.98 g/cm³. Removal rate, reported in microns/minute, is the average thickness reduction of the three wafers over the 30 minute polishing interval. Wafers were re-used for each 30 minute period.

### Preparation of Ceramic Abrasive Composite (CAC-1)

Ceramic abrasive composites were prepared from an aqueous dispersion, using a spray drying technique, as follows. Standex230, 49 g, was added to 1,100 g of deionized water and stirred continuously. After 10 minutes, 720 g of GF, was added over a 1 minute time interval. Note that the GF was ground down to a particle size of about 4.2 microns, prior to use. 880 g of MCD3A was then added to the solution with continual stirring. The solution was then atomized in a centrifugal atomizer, a MOBILE MINER 2000 from GEA Process Engineering A/S, Soborg, Denmark. The atomization wheel was running at 20,000 rpm. Air was supplied at 200° C. into the atomization chamber and was used to dry the droplets as they formed, producing spray dried, ceramic abrasive composites. The collected composites were then combined with AlOx, forming a 65/35 composite/AlOx (wt./wt.) powder blend. The powder blend was vitrified at 750° C. for 1 hr. After cooling, the vitrified, ceramic abrasive composites were passed through a conventional sieve having openings of about 63 microns. The collected vitrified, ceramic abrasive composites, having a particle size of about 63 microns and less were designated as CAC-1.

### Preparation of Lubricant

To 462 g of deionized water, 28.5 g of Carbopol Aqua 30 was added with 3 min of gentle mixing by rolling the closed container at about 20 rpm. Glycerol, 1388 g, was added to the water mixture and gently mixed for 30 minutes taking care to not entrap air bubbles. Kathon, 1.9 g was added to the water/glycerol solution and gently mixed for 15 minutes. An 18% sodium hydroxide and water solution, 8.5 g was added and the viscous solution was gently mixed for 30 minutes.

### Preparation of Slurry-1

A slurry was prepared by forming a glycerol/water solution containing 10 g CAC-1 and 990 g Lubricant. The solution was mixed using a conventional high shear mixer for about 3 minutes prior to use.

### Preparation of Pad for Comparative Example 1 (CE1)

A 25×25 in. sheet of Gen II Pad, 41-9103-5040-8, was laminated onto a sheet of 30 mil thick polycarbonate comprising 442KW double sided adhesive on both sides of the polycarbonate, with the Gen II Pad surface facing up. The pad was then die cut to fit the appropriate tool platen.

### Preparation of Pad for Examples 2-11, 13, 15-22, and 24

A 25×25 in. sheet of the indicated sheet or film material was treated on one side with a thin coating of Primer 94 (See Table 1). The primed side of the indicated sheet or film material was then laminated with a sheet of 300LSE double side adhesive with the release liner retained on the un-laminated side. The top surface of a 25×25 in. Gen II Pad from CE1 was treated with a thin coating of Primer 94. The release liner was removed from the 300LSE laminated sheet or film material and was then laminated with the primed Gen II Pad from CE1. The pad was then die cut to fit the appropriate tool platen.

### Preparation of Pad for Examples 12, 14, and 23

The top surface of a 25×25 in. Gen II Pad from CE1 was treated with a thin coating of Primer 94. The release liner was removed from a 25×25 in. sheet of the indicated sheet or film material which had been supplied with adhesive (See Table 1), and was then laminated with the primed Gen II Pad from CE1. The pad was then die cut to fit the appropriate tool platen.

### Preparation of Pad for Examples 25

A round sheet of polycarbonate, with 15″ diameter with 1″ center hole, including 442 kw adhesive on both sides, was attached to a 15″ aluminum platen. The top layer of 442 adhesive was then modified with YSZ grinding media, 1 mm, by spreading the particles over the top adhesive surface. A monolayer of YSZ particles adheres to the adhesive layer with an average gap of about 1 mm between media particles. Particles which piled were readily removed by inverting the coated polycarbonate sheet and platen. The particles were press tightly to the adhesive by applying an inverted 15″ aluminum platen on top of the particle spheres. This was allowed to build adhesion for 24 hrs. The top aluminum plate was removed and a 15″ diameter sheet of UHMWPE, 2 mil, was applied onto the YSZ particles with the adhesive side attaching to the YSZ particles. Using a rubber hand roller, the film was gently rolled over. The aluminum plate was applied over the UHMWPE film for an additional 24 hrs. The top platen was removed and the pad was tested according to Polishing Test Method-2.

### Preparation of Pad for Examples 26

A round sheet of polycarbonate, 15″ diameter with 1″ center hole and including 442 kw adhesive on both sides, was attached to a 15″ aluminum platen. A round sheet of polypropylene modified stem web, with 15″ outer diameter and 1″ inner diameter hole, was then affixed to the top layer of 442 adhesive with the stem side facing up. The stem side of the pad was then brushed w/ a paint brush dipped in Primer 94 over the entire surface. This pad was allowed to dry for 12 hrs. Lastly, a sheet of UHMWPE, 15″ diameter with a 1″ inner diameter hole and 2 mil in thickness, was applied onto the stem web. This pad was not tested.

TABLE 1

| | | | Film |
|---|---|---|---|
| | | | Thickness |
| Example | Base Pad Material | Laminate Material on Base Pad | (mil) |
| CE1 | Gen II Face Up Poly Propylene Pad Base | None | NA |
| 2 | Gen II Face Up Poly Propylene Pad Base | Nylon 6/6 Sheet | 30 |
| 3 | Gen II Face Up Poly Propylene Pad Base | Poly Carbonate Sheet | 25 |
| 4 | Gen II Face Up Poly Propylene Pad Base | Polyphenylene Sulfide Film | 5 |
| 5 | Gen II Face Up Poly Propylene Pad Base | ABS Film | 3 |
| 6 | Gen II Face Up Poly Propylene Pad Base | Tefzel (ETFE) Film | 5 |
| 7 | Gen II Face Up Poly Propylene Pad Base | Poly Carbonate Film | 5 |
| 8 | Gen II Face Up Poly Propylene Pad Base | Hytrel (TPE) Film | 3 |
| 9 | Gen II Face Up Poly Propylene Pad Base | Udel (Polysulfone) Film | 5 |
| 10 | Gen II Face Up Poly Propylene Pad Base | PEEK Film | 3 |
| 11 | Gen II Face Up Poly Propylene Pad Base | Ultem (Poletherimide) Film | 3 |
| 12 | Gen II Face Up Poly Propylene Pad Base | UMHW-PE Film w adhesive | 5 |
| 13 | Gen II Face Up Poly Propylene Pad Base | Kynar (PVDF) Film | 3 |
| 14 | Gen II Face Up Poly Propylene Pad Base | UMHW-PE Film w adhesive | 3 |
| 15 | Gen II Face Up Poly Propylene Pad Base | FEP Film | 3 |
| 16 | Gen II Face Up Poly Propylene Pad Base | PTFE Film | 3 |
| 17 | Gen II Face Up Poly Propylene Pad Base | UMHW-PE Film | 5 |
| 18 | Gen II Face Up Poly Propylene Pad Base | Polyoxymethylene Film | 4 |
| 19 | Gen II Face Up Poly Propylene Pad Base | Poly Ester Terephalate Film | 3 |
| 20 | Gen II Face Up Poly Propylene Pad Base | Poly Imide Film | 1 |
| 21 | Gen II Face Up Poly Propylene Pad Base | Poly Urethane Film | 5 |
| 22 | Gen II Face Up Poly Propylene Pad Base | TPX (Polymethylpentene) Film | 3 |
| 23 | Gen II Face Up Poly Propylene Pad Base | Poly Propylene Film w adhesive | 2 |
| 24 | Gen II Face Up Poly Propylene Pad Base | Surlyn Film | 2 |
| 25 | YTZ on 442/PC/442 | UMHW-PE Film w adhesive | 2 |
| 26 | Modified Stem Web | UMHW-PE Film w adhesive | 2 |

### Polishing Test—Examples CE1 to 25

The polishing test for examples CE1 to 24 were run on the Pad indicated in Table 1 with Polishing Test Method-1, Removal Rate Test Method-1, Surface Roughness Test Method-1 and Slurry-1. The test results are listed in Table 2. Example 25 was run on Polishing Test Method-2

TABLE 2

| | | Ave | | Ave | | Ave | | Ave |
|---|---|---|---|---|---|---|---|---|
| | Ave | RR | Ave | Ra | Ave | Rz | Ave | Rmax |
| Example | RR | Stdev | Ra | Stdev | Rz | Stdev | Rmax | Stdev |
| CE1 | 1.78 | 0.12 | 0.037 | 0.005 | 0.337 | 0.053 | 0.426 | 0.179 |
| 2 | 1.30 | 0.02 | 0.040 | 0.005 | 0.363 | 0.041 | 0.441 | 0.137 |
| 3 | 0.89 | 0.20 | 0.046 | 0.005 | 0.427 | 0.058 | 0.515 | 0.089 |
| 4 | 2.06 | 0.23 | 0.048 | 0.004 | 0.442 | 0.053 | 0.527 | 0.124 |
| 5 | 2.00 | 0.14 | 0.042 | 0.002 | 0.380 | 0.040 | 0.477 | 0.143 |
| 6 | 1.88 | 0.01 | 0.045 | 0.003 | 0.405 | 0.047 | 0.508 | 0.173 |
| 7 | 1.80 | 0.07 | 0.044 | 0.005 | 0.435 | 0.067 | 0.595 | 0.299 |
| 8 | 1.68 | 0.10 | 0.043 | 0.002 | 0.362 | 0.024 | 0.423 | 0.058 |
| 9 | 1.63 | 0.08 | 0.045 | 0.004 | 0.406 | 0.038 | 0.480 | 0.077 |
| 10 | 1.61 | 0.03 | 0.038 | 0.005 | 0.347 | 0.049 | 0.426 | 0.132 |
| 11 | 1.58 | 0.07 | 0.045 | 0.007 | 0.404 | 0.066 | 0.505 | 0.173 |
| 12 | 1.40 | 0.25 | 0.042 | 0.003 | 0.367 | 0.021 | 0.435 | 0.066 |
| 13 | 1.30 | 0.00 | 0.042 | 0.002 | 0.367 | 0.023 | 0.434 | 0.070 |
| 14 | 1.21 | 0.04 | 0.039 | 0.003 | 0.347 | 0.021 | 0.395 | 0.058 |
| 15 | 1.20 | 0.02 | 0.040 | 0.002 | 0.353 | 0.021 | 0.407 | 0.069 |
| 16 | 1.14 | 0.04 | 0.042 | 0.005 | 0.356 | 0.036 | 0.407 | 0.064 |
| 17 | 1.12 | 0.13 | 0.040 | 0.002 | 0.351 | 0.039 | 0.417 | 0.137 |
| 18 | 1.01 | 0.04 | 0.047 | 0.007 | 0.447 | 0.056 | 0.573 | 0.136 |
| 19 | 0.85 | 0.01 | 0.042 | 0.004 | 0.382 | 0.052 | 0.444 | 0.116 |
| 20 | 0.74 | 0.04 | 0.043 | 0.001 | 0.360 | 0.019 | 0.404 | 0.037 |
| 21 | 0.72 | 0.03 | 0.035 | 0.003 | 0.287 | 0.031 | 0.322 | 0.040 |
| 22 | 0.72 | 0.02 | 0.038 | 0.003 | 0.334 | 0.019 | 0.382 | 0.041 |
| 23 | 0.69 | 0.04 | 0.037 | 0.002 | 0.324 | 0.027 | 0.372 | 0.060 |
| 24 | 0.19 | 0.01 | 0.035 | 0.003 | 0.291 | 0.026 | 0.318 | 0.034 |
| 25 | 0.45 | | | | | | | |

Other embodiments of the invention are within the scope of the appended claims.

1. A polishing system comprising:
a substrate to be polished;
a polishing pad, the polishing pad comprising
a base layer;
a plurality of cavities that extend into the base layer from a first major surface of the base laver; and
a wear resistant layer disposed on the first major surface as an at least substantially planar layer that overlays the first major surface; and
a polishing solution disposed between the polishing pad and the substrate, the polishing solution comprising:
a fluid component; and
a plurality of ceramic abrasive composites, the ceramic abrasive composites comprising individual abrasive particles uniformly dispersed throughout a porous ceramic matrix;
wherein at least a portion of the porous ceramic matrix comprises glassy ceramic material; and
wherein the ceramic abrasive composites are dispersed in the fluid component.

2. The polishing system of claim 1, wherein the base layer has a first major surface that is positioned nearest the substrate, and wherein the wear resistant layer is disposed on the first major surface of the base layer.

3. The polishing system of claim 1,
wherein the wear resistant layer comprises ultra high molecular weight polyethylene.

4. The polishing system of claim 1,
wherein the wear resistant layer has an average thickness of between 1 and 5 mils.

5. The polishing system of any one of claim 1, wherein the base layer is polymeric.

6. The polishing system of any one of claim 1, wherein the base layer comprises polypropylene.

7. (canceled)

8. The polishing system of claim 1, wherein the fluid component comprises ethylene glycol, propylene glycol, glycerol, or oligomers of ethylene glycol.

9. The polishing system of claim 1, wherein the abrasive particles comprise diamond, cubic boron nitride, fused aluminum oxide, ceramic aluminum oxide, heated treated aluminum oxide, silicon carbide, boron carbide, alumina zirconia, iron oxide, ceria, or garnet.

10. The polishing system of claim 1, wherein the abrasive particles comprise diamond.

11. The polishing system of claim 1, wherein the ceramic abrasive composites have an average particle size of less than 500 microns

12. The polishing system of claim 1, wherein the average size of the ceramic abrasive composites is at least about 5 times the average size of the abrasive particles.

13. The polishing system of claim 1, wherein the porous ceramic matrix comprises glass comprising aluminum oxide, boron oxide, silicon oxide, magnesium oxide, sodium oxide, manganese oxide, or zinc oxide.

14. The polishing system of claim 1, wherein the concentration of the abrasive composites in the fluid component is between 0.065% and 6.5% by weight.

15. The polishing system of claim 1, wherein the porous ceramic matrix comprises at least 40% by weight glassy ceramic material.

16. A method of polishing a substrate, the method comprising:
providing a substrate to be polished;
providing a polishing pad comprising
a base layer;
a plurality of cavities that extend into the base laver from a first major surface of the base layer; and
a wear resistant layer disposed on the first major surface as an at least substantially planar layer that overlays the first major surface;
providing a polishing solution comprising
a fluid component; and
a plurality of ceramic abrasive composites, the ceramic abrasive composites comprising individual abrasive particles uniformly dispersed throughout a porous ceramic matrix;
wherein at least a portion of the porous ceramic matrix comprises glassy ceramic material; and
wherein the ceramic abrasive composites are dispersed in the fluid component;
positioning the polishing solution between the substrate and the polishing pad;
moving the substrate and polishing pad relative to one another such that the substrate is polished.
